(19) United States
(12) Patent Application Publication
(10) Pub. No.: US 2007/0158672 A1
(43) Pub. Date: Jul. 12, 2007

(54) FLAT LIGHT SOURCE AND MANUFACTURING METHOD THEREOF

(76) Inventors: Chao-Jen Chang, Taoyuan County (TW); Hon-We Wu, Taoyuan County (TW); Te-Chu Lu, Taoyuan County (TW); Cheng-Kuai Hsu, Taoyuan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/306,816

(22) Filed: Jan. 12, 2006

(51) Int. Cl. H01L 33/00

(52) U.S. Cl. 257/99

(57) ABSTRACT

A flat light source including a first substrate, ribs, a phosphor layer, a second substrate, electrode patterns and an insulating layer is provided. The ribs are disposed on the first substrate. The phosphor layer is disposed on the surface of the ribs. The second substrate is located above the first substrate. The electrode patterns are disposed on the second substrate, and each electrode pattern is aligned to one of the rib correspondingly. The insulating layer covers the surface of the electrode patterns. In particular, an inert gas is filled between the first and second substrates, and a discharge path is formed between the adjacent electrode patterns above the phosphor layer.

### BACKGROUND OF THE INVENTION

1. Field of Invention

The present invention relates to a light source and manufacturing method thereof. More particularly, the present invention relates to a flat light source and manufacturing method thereof.

2. Description of Related Art

Recently, the liquid crystal display panel (LCD panel) has become the main stream product for most of the display screens. However, as the LCD panel itself can not emit light, a back light module must be implemented under the LCD panel to provide light source to enable the LCD panel to display. The light source in the back light module is usually provided by luminescent lamp, and the light beam of the lamp passes through the optical film in the back light module and is dispersed so as to form a surface light source suitable for illuminating the LCD panel.

However, if using the flat light source directly, the utilization efficiency of the light beam can be improved and more even surface light source can be obtained. And, besides the flat light source can be applied as the back light source of the LCD panel, it can also be applied in other fields. Therefore, the flat light source has been developing with advantages.

In general, the flat light source is a plasma luminescent device, which can generate high-energy electrons by forming a high voltage difference between the electrode pairs, and the so-called plasma can be formed by high energy electrons bombarding inert gas. Thereafter, the excited atom in the plasma may release energy by a form of irradiating ultraviolet. And the emitted ultraviolet may further excite the phosphor in the flat light source to emit visible light.

FIG. 1 is a cross-sectional schematic diagram of a conventional flat light source. Referring to FIG. 1, in general, the electrode pair 104a, 104b of the conventional flat light source may be formed on the first substrate 100, and the dielectric pattern 106 may cover the electrode pair 104a, 104b. The phosphor layer 108 may be coated on the surface of the dielectric pattern 106. When an inert gas is filled between the first and the second substrates 100, 102, and a voltage is applied between the electrode pair 104a, 104b to generate high energy electrons, a discharge path 110 may be formed between the electrode pair 104a, 104b. However, as the discharge path 110 may pass through the phosphor layer 108, so that the phosphor layer 108 may be bombarded by the plasma continuously resulting in quick deterioration of the phosphor layer 108. Accordingly, the lifetime of the flat light source in use can not last long. In addition, in the conventional flat light source, both of the fire voltage and the sustain voltage to generate a high-energy electron between the electrode pair 104, 104b need a high voltage, so that the conventional flat light source still has the disadvantage of high power consumed.

### SUMMARY OF THE INVENTION

Accordingly, the present invention is directed to provide a flat light source to resolve the problems of short lifetime in use and the need of high fire voltage and sustain voltage of the conventional flat light source.

Another aspect of the present invention is to provide a manufacturing method of flat light source, and the flat light source fabricated by the method has long lifetime in use, and both of the fire voltage and the sustain voltage needed are low.

The present invention provides a flat light source, and the flat light source includes a first substrate, a plurality of ribs, a phosphor layer, a second substrate, a plurality of electrode patterns and an insulating layer. The ribs are disposed on the first substrate. The phosphor layer is disposed on the surface of the ribs. The second substrate is located above the first substrate. The electrode patterns are disposed on the second substrate, and each electrode pattern is aligned to corresponding one of the ribs, respectively. The insulating layer covers the surface of the electrode patterns. In particular, an inert gas is filled between the first and second substrates, and a discharge path is formed between the adjacent electrode patterns above the phosphor layer.

According to one preferred embodiment of the present invention, the height of the electrode pattern is between 5 and 300 microns.

According to one preferred embodiment of the present invention, the material of the electrode patterns includes a photosensitive conductive material. In one embodiment, the photosensitive conductive material includes metal particles inside.

According to one preferred embodiment of the present invention, the insulation layer includes a first insulation layer and a second insulation layer. The first insulation layer covers the side surfaces of the electrode patterns. The second insulation layer covers the top surfaces of the electrode patterns. In one embodiment, the material of the first insulation layer is different from the material of the second insulation layer.

According to one preferred embodiment of the present invention, the material of the ribs includes glass.

According to one preferred embodiment of the present invention, the height of the ribs is between 50 microns and 30 microns.

According to one preferred embodiment of the present invention, the flat light source of the present invention further includes a reflection layer, disposed on the surface of the first substrate.

The present invention also provides a manufacturing method of flat light source. First, a first substrate is provided, and a plurality of ribs are formed on the first substrate. Then, a phosphor layer is formed on the surfaces of the ribs. Next, a second substrate is provided, and a plurality of electrode patterns are formed on the second substrate and an insulation layer is formed on the surfaces of the electrode patterns. Next, the first and the second substrates are arranged in opposite position, and an inert gas is filled between the first and the second substrates. In particular, a discharge path is formed between the adjacent electrode patterns above the phosphor layer.

According to one preferred embodiment of the present invention, the method of forming the ribs on the first substrate includes molding the first substrate with the ribs using a molding manufacturing process.

According to one preferred embodiment of the present invention, the method of forming the ribs on the first substrate includes: a material layer is formed on the first substrate; a mask is formed on the material layer; a sand blast process is performed to define the ribs; and, the mask is removed.

According to one preferred embodiment of the present invention, the electrode patterns are formed on the second substrate. The method of forming the insulation layer on the surfaces of the electrode patterns includes that a first insulation layer is formed on the second substrate, wherein the first insulation layer may define a plurality of electrode regions on the second substrate. An electrode layer is formed in the electrode region to form the electrode patterns. A second insulation layer is formed on the top portion of the electrode patterns.

According to one preferred embodiment of the present invention, the method of forming the first insulation layer on the second substrate includes using a molding process.

According to one preferred embodiment of the present invention, the method of forming the first insulation layer on the second substrate includes performing a sand blast process.

According to one preferred embodiment of the present invention, the method of forming the electrode layer in the electrode regions includes that a plasma of electrode material is filled into the electrode regions directly; and, a drying process is performed.

According to one preferred embodiment of the present invention, the method of forming the electrode layer in the electrode regions includes that an electrode material is formed on the second substrate; and, a photolithography process is performed to pattern the electrode material. The electrode material disposed in the electrode regions is left.

According to one preferred embodiment of the present invention, the method of forming the electrode layer in the electrode regions includes that an electrode material is formed on the second substrate. A sand blast process is performed to pattern the electrode material, and the electrode material disposed in the electrode regions is left.

According to one preferred embodiment of the present invention, the method of forming the second insulation layer on the top portion of the electrode patterns includes performing a screen printing process.

According to the manufacturing method of flat light source of the present invention, as the electrode pair is made on the second substrate, the discharge path formed in the electrode pair can avoid the phosphor layer disposed on the first substrate. Accordingly, the chance that the phosphor layer is bombarded by the plasma is reduced substantially, so that the lifetime of the flat light source in use can be improved.

In order to the make the aforementioned and other objects, features and advantages of the present invention comprehensible, a preferred embodiment accompanied with figures is described in detail below.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a cross-sectional schematic diagram of a conventional flat light source.

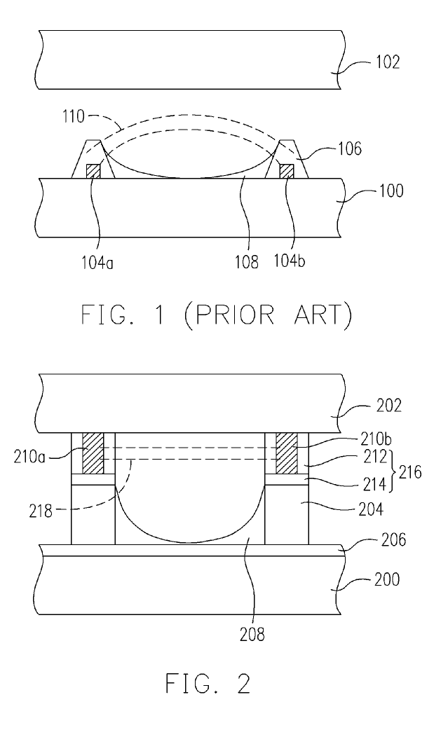

FIG. 2 is a schematic diagram of a flat light source according to one embodiment of the present invention.

FIG. 3 is a schematic diagram of a flat light source according to another embodiment of the present invention.

FIG. 4A to FIG. 4B are cross-sectional schematic diagrams of the manufacturing processes of the first substrate and the elements disposed on the first substrate of the flat light source according to one embodiment of the present invention.

FIG. 5A to FIG. 5B are cross-sectional schematic diagrams of the manufacturing processes of the first substrate and the elements disposed on the first substrate of the flat light source according to another embodiment of the present invention.

FIG. 6A to FIG. 6C are cross-sectional schematic diagrams of the manufacturing processes of the second substrate and the elements disposed on the second substrate of the flat light source according to another embodiment of the present invention.

FIG. 7 to FIG. 9 are cross-sectional schematic diagrams of the manufacturing processes of the electrode patterns on the second substrate according to the embodiment of the present invention.

### DESCRIPTION OF EMBODIMENTS

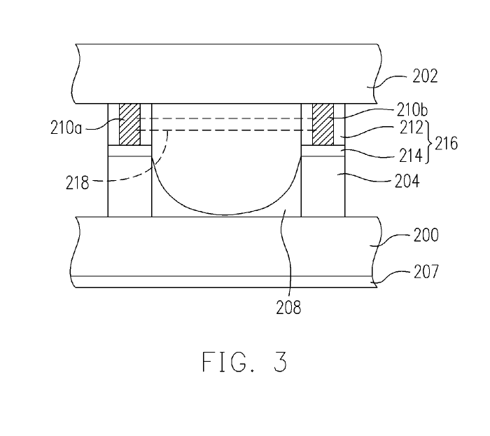

FIG. 2 is a schematic diagram of a flat light source according to one embodiment of the present invention. Referring to FIG. 2, the flat light source of the embodiment includes a first substrate 200, a plurality of ribs 204, a phosphor layer 208, a second substrate 202, a plurality of electrode patterns 210a, 210b and an insulation layer 216.

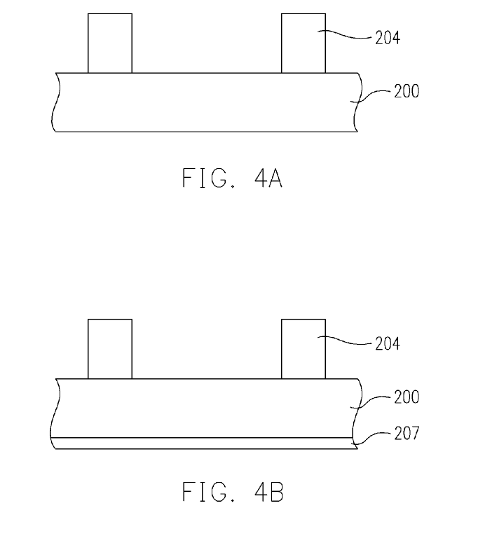

The material of the first substrate 200 and the second substrate 202 is, for example, transparent glass. The ribs 204 are disposed on the first substrate 200. In one embodiment, the material of the ribs 204 includes glass. In addition, the height of the ribs is, for example, between 50 microns and 300 microns. The phosphor layer 208 is disposed on the surface of the ribs 204. In another embodiment, a reflection layer 206 can also be further disposed on the surface of the first substrate 200, and the reflection layer 206 can lead the light beam created by the flat light source to transmit in reveal direction. In the flat light source as shown in FIG. 2, the reflection layer 206 is disposed between the first substrate 200 and the ribs 204. In another embodiment, as shown in FIG. 3, the reflection layer 207 is disposed on the bottom surface of the first substrate 200.

Moreover, the electrode patterns 210a, 210b are disposed on the second substrate 202, and each electrode pattern 210a or 210b is aligned to corresponding one of the ribs 204, respectively. In one embodiment, the height of the electrode patterns 210a, 210b is between 5 and 300 microns. The material of the electrode patterns 210a, 210b includes, for example, a photosensitive conductive material. The photosensitive conductive material includes metal particles, such as silver particles, aluminum particles, copper particles, or other metal conductive particles.

In addition, the insulation layer 216 covers the surfaces of the electrode patterns 210a, 210b. In one embodiment, the insulation layer 216 includes a first insulation layer 212 and a second insulation layer 214. The first insulation layer 212 covers the side surfaces of the electrode patterns 210a, 210b, and the second insulation layer 214 covers the top surfaces of the electrode patterns 210a, 210b. The material of the insulation layer 212 is different from the material of the second insulation layer 214. In one embodiment, the material of the first insulation layer 212 includes glass, and the material of the second insulation layer 214 includes metal oxide, such as zinc oxide or lead oxide, etc.

In particular, an inert gas is filled between the first substrate 200 and the second substrate 202. When a voltage is applied on the electrode patterns 210a, 210b, a discharge path 218 may be formed between the electrode patterns 210a, 210b above the phosphor layer 208. The excited atom of the plasma generated in the discharge path 218 may irradiate ultraviolet to excite the phosphor layer 110 to emit visible light. It is remarkable that, since the discharge path 218 in the flat light source of the present invention avoids the phosphor layer 208, the chance that the phosphor layer 208 is bombarded by the plasma is reduced substantially, so that the use life of the flat light source can be improved.

In addition, since the discharge path in the flat light source of the present invention is shorter than the discharge path of the conventional flat light source, both of the needed fire voltage and sustain voltage of the flat light source of the present invention are lower. As a result, the flat light source of the present invention has the advantage of lower power consumption, as the comparison data shown in TAB.1:

TABLE 1

| | Voltage | Current | Power | Brightness |
|---|---|---|---|---|
| The conventional plat | 24 V | 24 A | 576 W | 11974 nit |
| light source | | | | |
| The plat light source of | 17 V | 20 A | 340 W | 11965 nit |
| the present invention | | | | |

In TAB.1, in the same or similar brightness condition, the needed voltage of the conventional flat light source and the flat light source of the present invention is 24 V and 17 V, respectively, and the needed power of the conventional flat light source and the flat light source of the present invention is 576 W and 340 W, respectively. It can be learned that the flat light source of the present invention indeed consumes less power than the conventional flat light source.

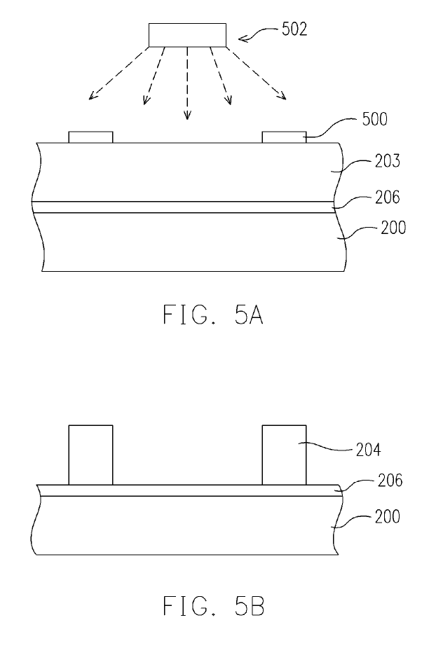

The manufacturing method of flat light source in FIG. 2 or FIG. 3 is described in the following. First, the ribs 204 are formed on the first substrate 200, and the formation method includes using a molding process. In more detail, referring to FIG. 4A, the glass is melted and molded into the first substrate 200 and the ribs 204 directly by mechanical molding process. Next, referring to FIG. 4B, the reflection layer 207 is attached on the bottom surface of the first substrate 200. Next, the first substrate 200 and the elements on the first substrate 200 are formed performing the phosphor layer coating process.

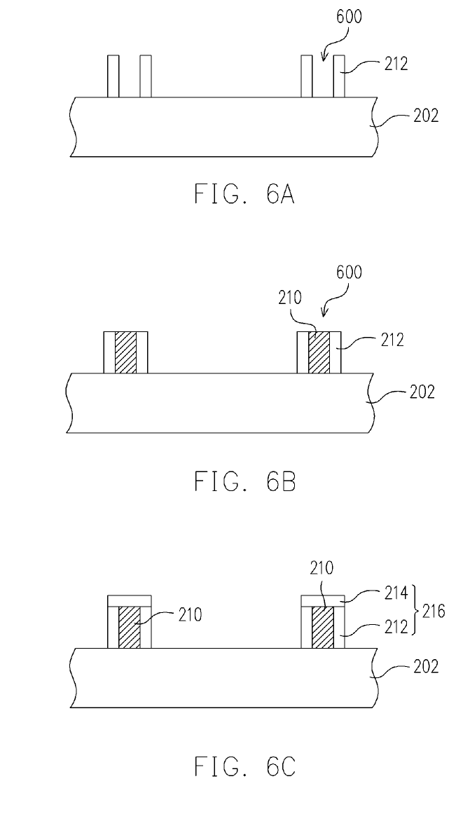

According to another embodiment of the present invention, the ribs 204 can also be formed on the first substrate 204 using a sand blast process. Referring to FIG. 5A for the detail, first, a reflection layer 206 is formed on the first substrate 200 by printing, coating, attaching or other suitable methods. A material layer 203, such as a glass layer, is formed on the reflection layer 206. Next, a mask 500 is formed on the glass layer 203 using, for example, attaching a dry film photoresist layer and performing a photolithography process. Next, a sand blast process 502 is performed to remove the glass layer 203 not covered by the mask 500. Next, referring to FIG. 5B, the mask 500 is removed to form the ribs 204, and the reflection layer 206 is formed between the ribs 204 and the first substrate 200. Next, as shown in FIG. 2, the first substrate 200 and the elements disposed on the first substrate 200 are then formed by performing the phosphor layer coating process.

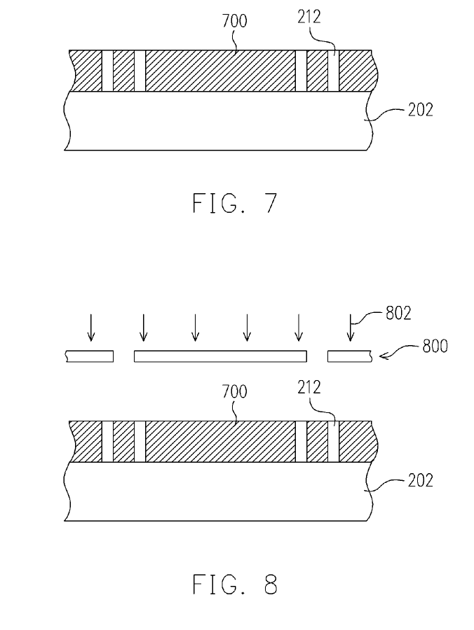

Moreover, the manufacturing method of the second substrate 200 and the elements on the second substrate 200 is described as follows. First, referring to FIG. 6A, the first insulation layer 212 is formed on the second substrate 202, wherein the first insulation layer 212 may define a plurality of electrode regions 600 on the second substrate 200. And, the method of forming the first insulation layer 212 on the second substrate 202 is, for example, using a molding process or a sand blast manufacturing process. That is, the glass can be melted and molded into the second substrate 202 and the first insulation layer 212 directly by mechanical molding method. Or, a glass layer (not shown) is coated on the second substrate 202, and a mask (not shown) is formed on the glass layer, then, a sand blast is performed to form the first insulation layer 212 on the second substrate 202.

Next, referring to FIG. 6B, an electrode layer 210 is formed in the electrode region 600, so as to form the electrode patterns 210a, 210b as shown in FIG. 2 and FIG. 3. And, the method of forming an electrode layer 210 in the electrode region 600 includes, for example, that an electrode material plasma is filled into the electrode region 600 directly; then, a drying process is performed to fix the electrical material plasma. The abovementioned electrode material plasma is, for example, the plasma including silver particles, copper particles, aluminum particles or other metal particles.

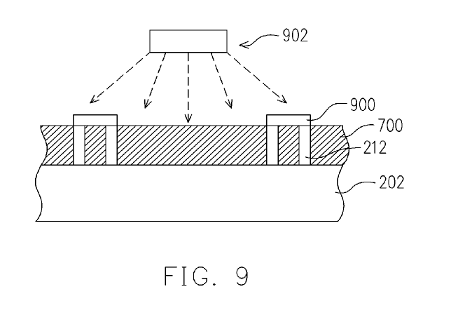

In another embodiment, as shown in FIG. 7, the method of forming an electrode layer 210 in the electrode region 600 includes that, first, an electrode material 700 is full-scale formed on the second substrate 202. Next, as shown in FIG. 8, a mask 800 is disposed above the second substrate 202, and an exposure process 802 is performed, so that the pattern on the mask 800 is transferred to the electrode material 700. Thereafter, as the structure shown in FIG. 6B, a developing process is performed to remove a part of the electrode material 700, so as to leave the electrode layer 210 within the electrode region 600.

In also another embodiment, as shown in FIG. 7, the method of forming the electrode layer in the electrode regions includes, first, an electrode material 700 being full-scale coated on the second substrate 202. Thereafter, as shown in FIG. 9, a mask 900 is formed on the electrode material 700, and a sand blast process 902 is performed to remove the electrode material 700 not covered by the mask 900, so as to leave the electrode layer 210 within the electrode region 600, as the structure shown in FIG. 6B.

After the manufacturing process of the electrode layer 210 is completed, referring to FIG. 6C, a second insulation layer 214 is formed on the top of the electrode layer 210 by, for example, printing process. So that, the side surface of the electrode layer 210 is covered by the first insulation layer 212, and the top surface is covered by the second insulation layer 214.

Finally, the first substrate 200 and the second substrate 202 are set to be opposite to each other, and an inert gas is filled between the first and the second substrates 200, 202, so that the manufacturing of flat light source is completed.

In summary, in the flat light source and manufacturing method thereof of the present invention, the electrode pairs are formed on the second substrate, so that the discharge path formed between the adjacent electrode pair can avoid the phosphor layer on the first substrate. Accordingly, the chance of the phosphor layer bombarded by the plasma is reduced substantially, and the lifetime of the flat light source in use can be improved. In addition, since the path of the discharge path is shortened, the needed fire voltage and the sustain voltage of the flat light source of the present invention can be reduced, so that the flat light source of the present invention has the advantage of power saving.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A flat light source, including:
a first substrate;
a plurality of ribs, disposed on the first substrate;
a phosphor layer, disposed on the surfaces of the ribs;
a second substrate, located above the first substrate;
a plurality of electrode patterns, disposed on the second substrate, and each electrode pattern is aligned to one of the ribs correspondingly; and
an insulating layer, covering the surfaces of the electrode patterns,
wherein, an inert gas is filled between the first and second substrates, and a discharge path is formed between the adjacent electrode patterns above the phosphor layer.

2. The flat light source as claimed in claim 1, wherein a height of the electrode pattern is between 5 and 300 microns.

3. The flat light source as claimed in claim 1, wherein a material of the electrode patterns includes a photosensitive conductive material.

4. The flat light source as claimed in claim 3, wherein the photosensitive conductive material includes metal particle.

5. The flat light source as claimed in claim 1, wherein the insulation layer includes a first insulation layer and a second insulation layer, and the first insulation layer covers a side surface of the electrode patterns, and the second insulation layer covers a top surface of the electrode patterns.

6. The flat light source as claimed in claim 5, wherein a material of the first insulation layer is different from a material of the second insulation layer.

7. The flat light source as claimed in claim 1, wherein a material of the ribs includes glass.

8. The flat light source as claimed in claim 1, wherein a height of the ribs is between 50 microns and 300 microns.

9. The flat light source as claimed in claim 1, further including a reflection layer, disposed on a surface of the first substrate.

10. A manufacturing method of flat light source, comprising:
providing a first substrate;
forming a plurality of ribs, on the first substrate;
forming a phosphor layer on a surface of the ribs;
providing a second substrate;
forming a plurality of electrode patterns on the second substrate, wherein an insulation layer is formed on the surfaces of the electrode patterns; and
arranging the first and the second substrates in an opposite position, wherein an inert gas is filled between the first and the second substrates,
wherein, a discharge path is formed between the adjacent electrode patterns above the phosphor layer.

11. The manufacturing method of flat light source as claimed in claim 10, wherein the step of forming the ribs on the first substrate comprises molding the first substrate with the ribs using a molding manufacturing process.

12. The manufacturing method of flat light source as claimed in claim 10, wherein the step of forming the ribs on the first substrate comprises: forming a material layer on the first substrate;
forming a mask on the material layer;
performing a sand blast process to define the ribs; and
removing the mask.

13. The manufacturing method of flat light source as claimed in claim 10, wherein the electrode patterns are formed on the second substrate, and the step of forming the insulation layer on the surface of the electrode patterns includes:
forming a first insulation layer on the second substrate, wherein the first insulation layer defines a plurality of electrode regions on the second substrate;
forming an electrode layer in the electrode regions to form the electrode patterns; and
forming a second insulation layer on a top portion of the electrode patterns.

14. The manufacturing method of flat light source as claimed in claim 13, wherein the step of forming the first insulation layer on the second substrate includes using a molding process.

15. The manufacturing method of flat light source as claimed in claim 13, wherein the step of forming the first insulation layer on the second substrate includes performing a sand blast process.

16. The manufacturing method of flat light source as claimed in claim 13, wherein the step of forming the electrode layer in the electrode regions includes:
directly filling a plasma of electrode material into the electrode regions; and
performing a drying process.

17. The manufacturing method of flat light source as claimed in claim 13, wherein the step of forming the electrode layer in the electrode regions includes:
forming an electrode material on the second substrate; and
performing a photolithography process to pattern the electrode material, and the electrode material disposed in the electrode regions being left.

18. The manufacturing method of flat light source as claimed in claim 13, wherein the step of forming the electrode layer in the electrode regions includes:
forming an electrode material on the second substrate; and
performing a sand blast process to pattern the electrode material, and the electrode material disposed in the electrode regions is left.

19. The manufacturing method of flat light source as claimed in claim 13, wherein the step of forming the second insulation layer on the top portion of the electrode patterns includes performing a screen printing process.
